(19) United States
(12) Patent Application Publication
(10) Pub. No.: US 2011/0077893 A1
(43) Pub. Date: Mar. 31, 2011

(54) Delay Test Apparatus, Delay Test Method and Delay Test Program

(75) Inventor: Noriyuki ITO, Kawasaki (JP)

(73) Assignee: FUJITSU LIMITED, Kawasaki-shi (JP)

(21) Appl. No.: 12/889,757

(22) Filed: Sep. 24, 2010

(30) Foreign Application Priority Data
Sep. 25, 2009 (JP) 2009-220642

(51) Int. Cl. G06F 19/00; G06F 17/18; G01R 31/26

(52) U.S. Cl. 702/117

(57) ABSTRACT

A delay test apparatus for a semiconductor integrated circuit includes (1) a selecting unit that selects at least one pair of a beginning latch and an ending latch based on layout information of the semiconductor integrated circuit, the pair of the beginning latch and the ending latch possibly representing a critical path, (2) an analyzing unit that calculates a delay distribution for the selected critical path by executing statistical static timing analysis which accumulates a delay period, defined as a probability density function for each element, from the beginning latch to the ending latch selected by the selecting unit, and (3) a test generating unit that generates delay test data for the selected critical path by determining whether a signal inverted at the beginning latch is propagated to the ending latch based on the delay distribution calculated by the analyzing unit.

### CROSS-REFERENCE TO RELATED APPLICATION

This application is based upon and claims the benefit of priority of the prior Japanese Patent Application No. 2009-220642, filed on Sep. 25, 2009, the entire contents of which are incorporated herein by reference.

### FIELD

The present invention relates to a delay test apparatus, a delay test method and a delay test program.

### BACKGROUND

In the post-production tests on a processor that is a semiconductor integrated circuit and serves as an arithmetic processing unit, it is important to test the chip independently with respect to whether the chip actually operates at the target frequency, in addition to a function test of whether the processor simply functions according to the specification. Among these tests, there is a delay test for estimating a delay by performing timing analysis.

Timing analysis is an analysis method of estimating the operating frequency of the chip using a CAD tool in the design stage to check if the target operating frequency is realized. For example, in designing a processor with a target operating frequency of 2.5 GHz, analysis is conducted as to whether signals propagate among all memory devices within the time of 400 ps, the reciprocal of 2.5 GHz.

Timing analysis is typically classified into static timing analysis and dynamic timing analysis. Static timing analysis is classified into two types: conventional static timing analysis (hereafter referred to as “STA”) and statistical static timing analysis (hereafter referred to as “SSTA”), which has been proposed in recent years.

The known STA methods include deterministic static timing analysis, path-based STA and block-based STA, whereas known SSTA methods include path-based SSTA and block-based SSTA.

STA, SSTA and block-based SSTA will be described below with reference to FIG. 10.

In STA, in order to calculate the delay along a path, the delay values of the elements forming the path, such as gate devices and wires are calculated cumulatively toward the subsequent stages. Here, the delay values are single definite values. In performing such cumulative calculation, path-based STA handles paths, considering the depth of the circuit preferentially; block-based STA handles paths, considering the width of the circuit preferentially.

In the example of FIG. 10, path-based STA handles the path from a latch 961 to a latch 963, the path from a latch 962 to a latch 963, and the path from a latch 962 to a latch 964 in the order presented.

In block-based STA, the delay values are simultaneously accumulated from both the latches 961 and 962 toward the output on a one gate-by-one gate basis. A gate 965 has two inputs; therefore, when delay value accumulation along the two paths, one from the latch 961 to the gate 965 and the other from the latch 962 to the gate 965, is completed, the process of accumulating the delay of the gate 965 is performed. As for the process of obtaining the maximum delay, the delay of the gate 965 is accumulated on the larger of the respective cumulative delays of the two paths leading to the gate 965 and then the process proceeds. In a case where one gate has multiple inputs as seen above, the process of selecting the largest delay is called a max operation.

Unlike in the above-mentioned STA, in SSTA, the delay values of the elements forming a path, such as gate devices and wires, are not single definite values but are represented by probability density functions with the delay value as the horizontal axis and the probability density as the longitudinal axis. As for the accumulation of the delays of paths, in STA, numerical values are simply added; in SSTA, probability density functions are added statistically. Also, in STA, a max operation is a numerical operation for leaving a simple, large value; in SSTA, a statistical operation of two probability density functions called “statistical max” is performed. Of the SSTA methods, block-based SSTA handles paths, considering the width preferentially, as with block-based STA.

Referring now to FIGS. 11A and 11B, STA and SSTA will be further described. Conventionally, a critical path, which is assumed to be a path along which signal transmission is delayed, is selected from the paths in a circuit based on the result of STA (see FIG. 11A). When manufacturing processors, for example, insufficient flatness of wiring layers or variations in the number of impurity atoms causes variations in performance among products (product variations). In STA, a max operation is performed with respect to the delay value of each element in the chip, and analysis is performed postulating the largest (worst) delay value.

It is known that selection of a critical path based on only the result of STA does not necessarily ensure accurate selection of a path that is critical on the actual chip. This is because the probability that all the elements in the processor have the worst values is extremely small and therefore the method using STA makes an unrealistic estimation as well as overestimates the delay, resulting in increased man-hours of timing design.

In STA, the delay value of the critical path is represented by a single value; however, in actual chips, the delay value varies from chip to chip due to manufacturing variations or the like. For this reason, there is known a method of selecting a critical path based on the result of SSTA rather than based on the result of STA (see FIG. 11B). SSTA is a method of handling the delay value of each element not as a single value but as a probability distribution as described above, so the possibility that each path is a critical path on the actual chip can be represented by a probability.

Also, in a delay test for determining whether, after manufacturing processors, each processor is faulty or not in terms of delay, a test pattern intended to obtain a critical path is generated and the processors are tested one by one using the test pattern. However, due to the limited memory of the tester or the time limit of the test, the number of testable paths is on the order of several thousands, as compared to the total number of paths on the order of several tens of millions. Also, due to manufacturing variations, the critical path varies among actually manufactured processors.

The following technologies are known.
[Patent Document 1] Japanese Laid-open Patent Publication No. 2005-308471
[Patent Document 2] Japanese Laid-open Patent Publication No. 2004-150820
[Non-Patent Document 1] Vikram Iyengar et al., “Variation-Aware Performance Verification Using At-Speed Structural Test And Statistical Timing,” International Conference on Computer Aided Design, pp 405-412, 2007.

Technologies for analyzing integrated circuits using SSTA have been disclosed as the related art. In the conventional SSTA methods, however, SSTA (block-based SSTA) is applied to an entire integrated circuit to be tested, so it is difficult to list up unique paths using SSTA as critical paths. Specifically, in conventional SSTA, the distribution is calculated in each stage starting with the beginning latch to obtain the distribution of a path leading to the ending latch. As seen above, only the result mentions the entire integrated circuit, so it is not possible to narrow down paths.

In the related art, in order to narrow down paths, the index “criticality” is assigned to each pin of each gate, pins are then selected in the descending order of criticality, and critical paths passing through the selected pins are selected. In selecting critical paths passing through the pins, a path having the smallest margin is selected based on a statistic slack (a statistically calculated slack of slacks representing a timing margin).

The problem with this method is that when conducting a test, a meaningless path (a false path) may be selected and whether a selected path is a false path cannot be determined at the time of selection. The false path is not logically activated in terms of logical design and logically no possibility of being passed through. For this reason, the conventional method employs a trial and error technique by which whether a selected path has a possibility of being a false path is determined using a certain index and, if the path has such a possibility, another path is added.

### SUMMARY

According to an aspect of the invention, a delay test apparatus for a semiconductor integrated circuit includes (1) a selecting unit that selects at least one pair of a beginning latch and an ending latch based on layout information of the semiconductor integrated circuit, the pair of the beginning latch and the ending latch possibly representing a critical path, (2) an analyzing unit that calculates a delay distribution for the selected critical path by executing statistical static timing analysis which accumulates a delay period, defined as a probability density function for each element, from the beginning latch to the ending latch selected by the selecting unit, and (3) a test generating unit that generates delay test data for the selected critical path by determining whether a signal inverted at the beginning latch is propagated to the ending latch based on the delay distribution calculated by the analyzing unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a diagram illustrating a method for applying SSTA to an entire integrated circuit;

FIG. 1B is a diagram illustrating a method for applying SSTA to each pair of a beginning latch and an ending latch according to this embodiment;

FIG. 2 is a diagram illustrating a delay test apparatus according to this embodiment;

FIG. 3 is a flowchart illustrating the operation of the delay test apparatus according to this embodiment;

FIG. 4 is a diagram illustrating the selection of worst N paths according to this embodiment;

FIG. 5 is a schematic diagram of a circuit illustrating “a path is not logically activated” according to this embodiment;

FIG. 6 is a diagram illustrating paths testable using the same test pattern according to this embodiment;

FIG. 7 is a diagram illustrating paths untestable using the same test pattern according to this embodiment;

FIG. 8 is a diagram illustrating the hardware configuration of a computer system applicable to the delay test apparatus according to this embodiment;

FIG. 9 is a diagram illustrating the hardware configuration of the main body of the computer system applicable to the delay test apparatus according to this embodiment;

FIG. 10 is a schematic diagram of a circuit illustrating STA and SSTA; and

FIGS. 11A and 11B are diagrams illustrating STA and SSTA, respectively.

### DESCRIPTION OF EMBODIMENTS

Preferred embodiments of the present invention will be explained with reference to accompanying drawings.

In this embodiment, the design data of an integrated circuit to be tested is first analyzed using STA to obtain critical paths on the integrated circuit. Then, at least one of the obtained critical paths is extracted, and SSTA is applied to the logic circuits between a pair of the extracted critical path's beginning and ending latches. In this embodiment, for example, block-based SSTA is applied.

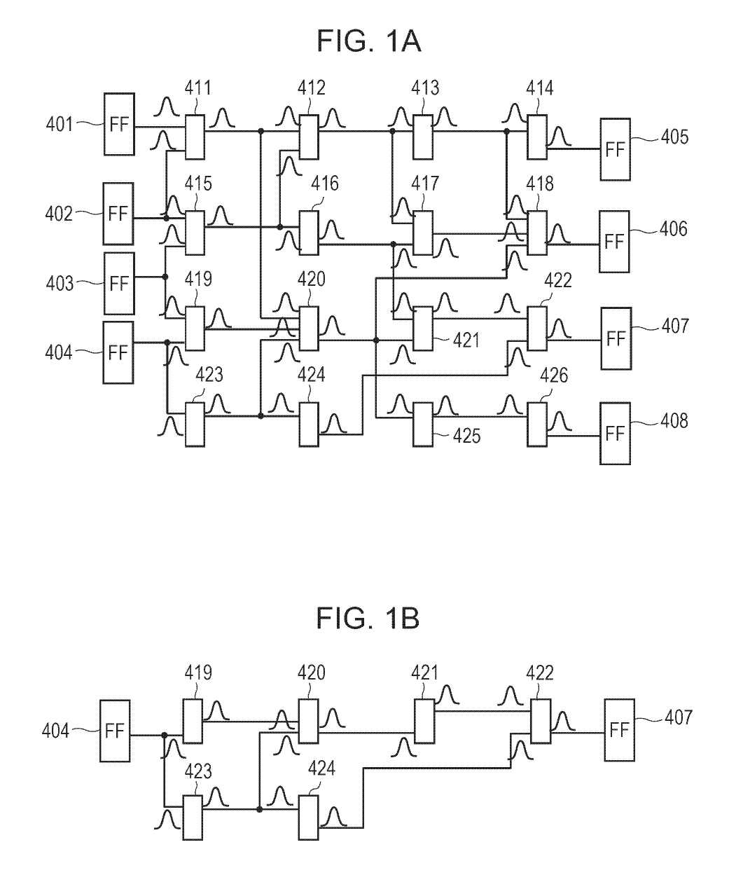

FIG. 1A is a diagram illustrating the application range of block-based SSTA according to the related art and FIG. 1B is a diagram illustrating the application range of block-based SSTA according to this embodiment. In the diagrams, beginning latches 401 to 404 and ending latches 405 to 408 constitute flip-flop (FF) circuits, and multiple logic circuits 411 to 426 are connected between these latches. In the related art, block-based SSTA is applied to the entire integrated circuit; in this embodiment, block-based SSTA is applied to the logic circuits 419 to 424 between the beginning latch 404 and ending latch 407 forming a pair regarded as a critical path as the result of STA.

In this embodiment, attempts are made to generate a test pattern until one logically activated path is found among the paths between the beginning latches and ending latches. Also, in this embodiment, pattern data with which multiple paths are to be tested in a single delay test is generated in a manner containing no paths having the same ending latch. This allows identification of false paths based on latches that have failed in the test performed on the manufactured integrated circuit.

Hereafter, this embodiment will be described in detail. In the following description, it is assumed that the integrated circuit to be tested is a processor, however, this embodiment is applicable to any type of integrated circuit.

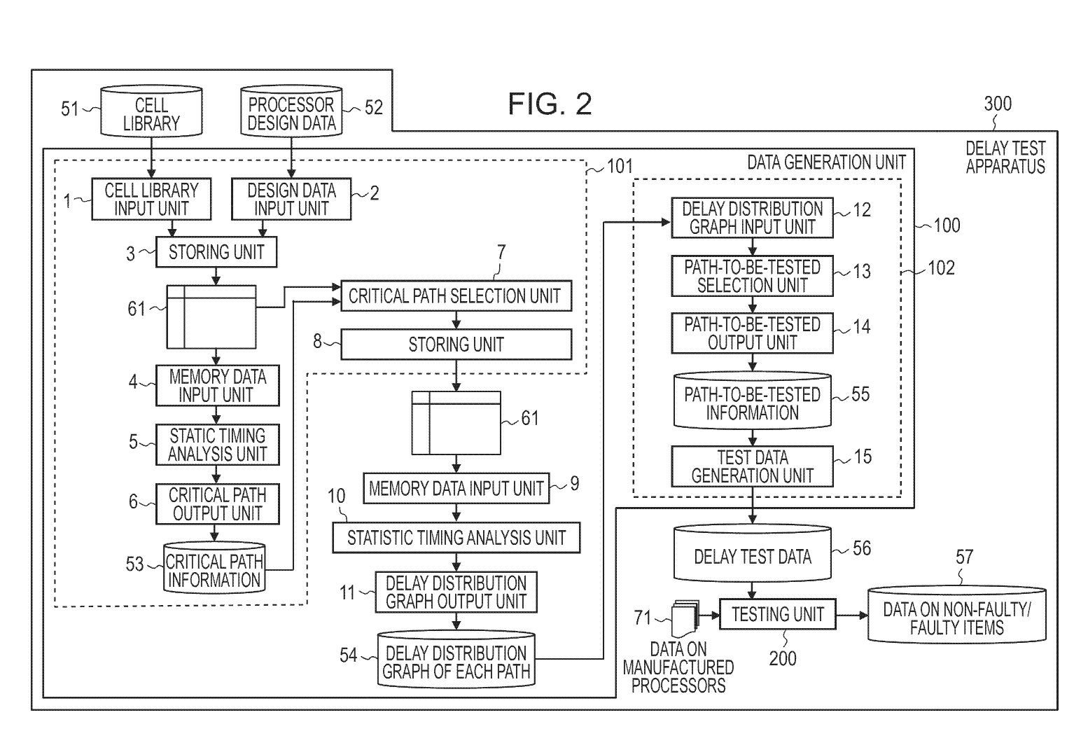

FIG. 2 illustrates a delay test apparatus according to this embodiment. A delay test apparatus 300 includes a data generation unit 100 and a testing unit 200.

The data generation unit 100 receives a conventional cell library 51 and processor design data 52 of the processor to be tested, and outputs delay test data 56 for use in a delay test. The testing unit 200 conducts a conventional delay test on a manufactured processor in accordance with the delay test data 56 generated by the data generation unit 100 and data 71 of the processor. It then outputs result data 57 as to whether the processor can be shipped (non-faulty item) or not (faulty item).

The data generation unit 100 will be described in detail. The data generation unit 100 includes a cell library input unit 1 that obtains the cell library 51, a design data input unit 2 that obtains the processor design data 52, and a storing unit 3 that causes a memory 61 to store the cell library 51 and the processor design data 52.

The data generation unit 100 also includes a memory data input unit 4 that obtains the cell library 51 and processor design data 52 stored in the memory 61, and a static timing analysis unit 5 that performs STA analysis using the cell library 51 and the processor design data 52 and identifies multiple critical paths, which may delay signal propagation in the processor, within the range in which STA analysis can be performed. The data generation unit 100 also includes a critical path output unit 6 that outputs critical path information 53, which is information on the critical paths identified by the static timing analysis unit 5.

The data generation unit 100 also includes a critical path selection unit 7 that, using the critical path information 53 and the cell library 51 and processor design data 52 stored in the memory 61, selects the necessary number of pairs of beginning latches and ending latches, disposed in paths that may delay signal propagation in the processor. Hereafter, the pairs thus selected will be referred to as “worst N paths.” The number of worst N paths is set to a number such that the quality of a test conducted by the testing unit 200 is regarded as being sufficient, and will be described later.

The data generation unit 100 also includes a storing unit 8 that causes the memory 61 to store the pairs of beginning latches and ending latches selected by the critical path selection unit 7.

The data generation unit 100 also includes a memory data input unit 9 that obtains the cell library 51, processor design data 52, and worst N paths stored in the memory 61. The data generation unit 100 also includes a statistic timing analysis unit 10 that applies block-based SSTA to all the logic circuits between the beginning latch and ending latch of each path obtained by the memory data input unit 9 so as to generate a delay distribution. The data generation unit 100 also includes a delay distribution graph output unit 11 that outputs the delay distribution generated by the statistic timing analysis unit 10 as a delay distribution graph 54.

The data generation unit 100 also includes a delay distribution graph input unit 12 that obtains the delay distribution graph 54, and a path-to-be-tested selection unit 13 that calculates the value of α×σ (α is a constant and σ is the standard deviation) of each delay distribution and sorts the paths respectively having beginning latches and ending latches in the descending order of the values calculated. The data generation unit 100 also includes a path-to-be-tested output unit 14 that outputs information on the sorted paths as path-to-be-tested information 55.

The data generation unit 100 also includes a test data generation unit 15 that assumes that there is a transition fault, one of delay fault models, in a logic circuit between the beginning latch and the ending latch and generates the delay test data 56 for each such assuming fault.

The elements ranging from the cell library input unit 1 to the storing unit 8 constitute a pair selection unit 101, and the elements ranging from the delay distribution graph input unit 12 to the test data generation unit 15 constitute a delay test data generation unit 102.

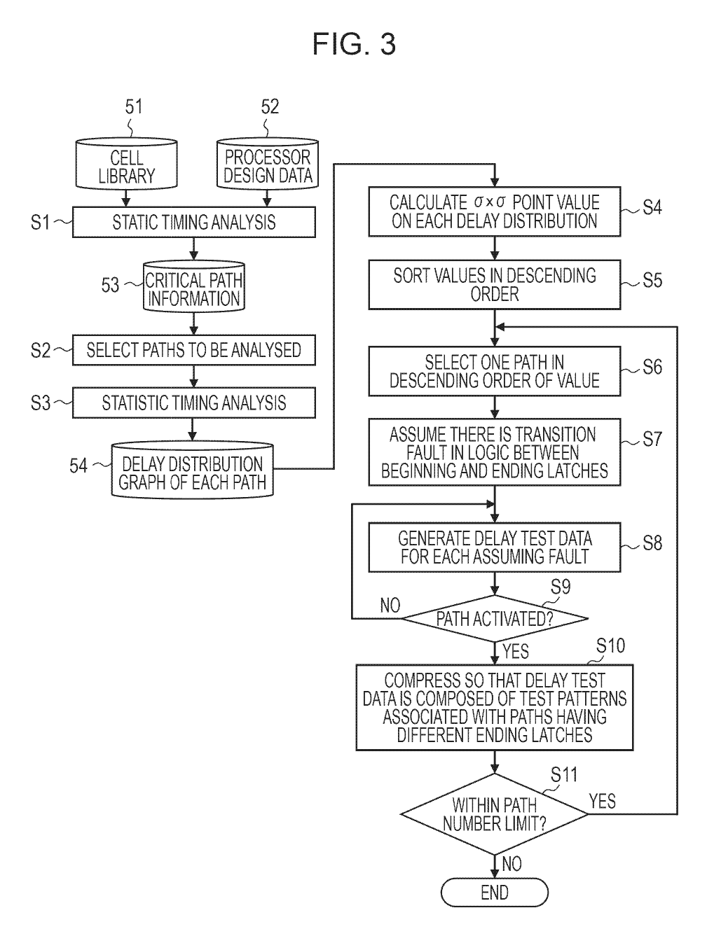

Now referring to FIG. 3, the operation of the delay test apparatus 300 will be described. In the following description, the units that receive or outputs data, such as the storing unit 3 and memory data input unit 4, will be omitted.

The static timing analysis unit 5 performs the conventional STA process on the cell library 51 and processor design data 52 and outputs the critical path information 53 (S1). The critical path selection unit 7 then selects the worst N paths from the critical path information 53 (S2).

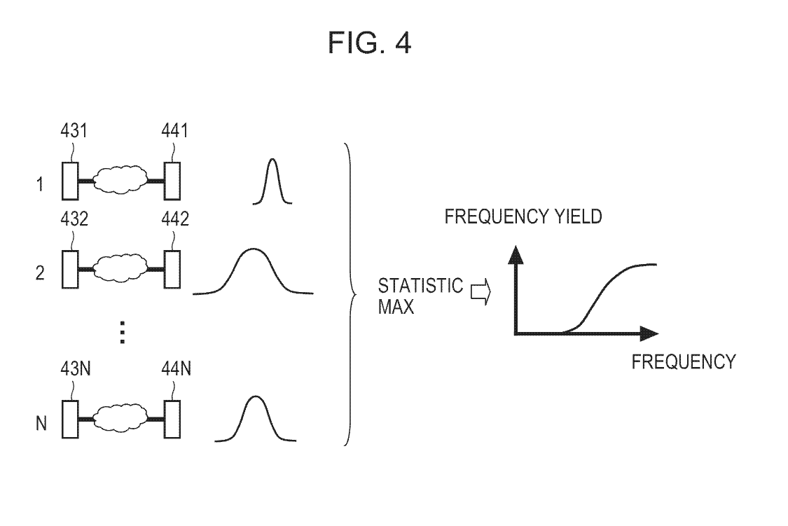

How to obtain the number of paths to be selected as the worst N paths will be described with reference to FIG. 4. First, the critical path selection unit 7 obtains the frequency yield distribution of the entire chip from the delay distributions of the N number of pairs of beginning latches 431 to 43N and ending latches 441 to 44N as illustrated in FIG. 4, and then obtains the frequency yield distribution of the entire chip from the delay distributions of the (N+1) number of pairs of beginning latches and ending latches. If the difference between the obtained two frequency yield distributions is equal to or smaller than a predetermined value, the data on the (N+1)th path is unnecessary and N is regarded as the number of worst N paths.

The frequency yield of the entire chip refers to a distribution graph generated by actually measuring the maximum operating frequency with respect to each of manufactured chips and using the maximum operating frequency as the horizontal axis and the proportion of the chip number as the longitudinal axis. Also, in this embodiment, the difference between the frequency yield distributions is defined as the difference between the maximum operating frequency values on the horizontal axis of two distributions at the target proportion value on the longitudinal axis, and if this difference is equal to or smaller than the predetermined value, it is determined that there is no difference. How small the predetermined value is depends on the accuracy to be obtained.

FIG. 3 will be referred to again. The statistic timing analysis unit 10 then performs a block-based SSTA process on each pair of the beginning latch and the ending latch selected by the critical path selection unit 7 to generate delay distribution graphs 54 with respect to the paths in the pairs (S3). In this block-based SSTA process, statistic delay operations are performed on the range illustrated in FIG. 1B, that is, all the logic circuits 419 to 424 between the beginning latch 404 and the ending latch 407. That is, delay distributions considering all the paths between the beginning latch 404 and the ending latch 407 that are obtained.

The path-to-be-tested selection unit 13 calculates the delay value of the α×σ point with respect to each of the delay distributions thus obtained (S4) and sorts the delay values in the descending order (S5). In this embodiment, for example, α is set to −3. The reason for sorting the point values in the descending order is that even when a path delay is reduced due to manufacturing variations, testing paths starting with a path making a larger delay increases the possibility that a delay fault can be detected. Note that a may be 3 or other values.

The path-to-be-tested selection unit 13 selects one path in the sorted order (S6). Then, according to the conventional method, the data generation unit 15 assumes that there are assuming faults, transition faults, on the path between the beginning and ending latches (S7) and generates a delay test pattern with respect to each of the assuming faults (S8). At that time, the test data generation unit 15 determines whether the path is logically activated (S9). If the path is not logically activated (S9, no), the operation returns to S8 and the above-mentioned process is performed on the next path. If the path is logically activated (S9, yes), the operation proceeds to S10.

S8 and S9 will be described in detail. The test data generation unit 15 tries to generate patterns with respect to the above-mentioned assuming faults so that signal variations occur between the beginning and ending latches of the path to be processed. If the path is not logically activated, the test data generation unit 15 tries to generate a test pattern with respect to the next assuming fault. When successfully generating even one pattern, the test data generation unit 15 ceases to generate a test pattern with respect to the pair to be processed. With regard to processors, it is known as an empirical rule that the number of stages of any latch-to-latch path is constant. Whatever path is selected is similar to a path making the largest delay. Accordingly, in this embodiment, when successfully generating even one pattern, pattern generation with respect to the path to be processed is completed.

The test data generation unit 15 makes tries with respect to all the assuming faults and, if the path is not logically activated, completes the process with respect to that pair.

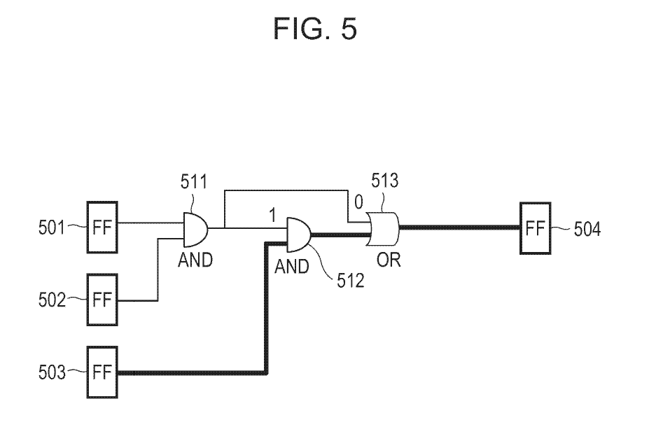

“A path is not logically activated” will be described with reference to FIG. 5. In the example of FIG. 5, the path from a latch 503 through gates 512 and 513 to a latch 504 is subjected to a delay test. If signal variations caused by the latch 503 can propagate along this path to the latch 504, the path from the latch 503 to the latch 504 is open. However, in the example of FIG. 5, the path from the latch 503 to the latch 504 is not logically activated. In order for the latch 503-to-latch 504 path to be logically activated, the input not present on the path, of the two inputs of the gate 512 must be 1 because the gate 512 is an AND circuit. On the other hand, the input not present on the path, of the two inputs of the gate 513 must be 0 because the gate 513 is an OR circuit. This requires that the output of a gate 511 be 1 for the gate 512 as well as 0 for the gate 513, which is logically impossible. For this reason, the path from the latch 503 to the latch 504 is not logically activated. That is, the path from the latch 503 to the latch 504 is a false path. Since the circuit illustrated in FIG. 5 includes redundant logic circuits, a false path occurs. Such redundant logic circuits may consequently be generated independently of the designer's intention.

FIG. 3 will be referred to again. The test data generation unit 15 does not generate test patterns with respect to paths having the same ending latch. Thus, the test data generation unit 15 compresses the delay test data 56 so that the data 56 is composed of test patterns associated with paths having different ending latches. The path-to-be-tested selection unit 13 then determines whether the number of paths falls within the path number limit (S11). If the number of paths exceeds the path number limit (S11, no), the data generation unit 100 completes the process, completing generation of the delay test data 56. If the number of paths falls within the path number limit (S11, yes), the operation returns to S6 and the above process is performed on the second maximum path.

S10 and S11 will be described in detail. The value of the scan chain is set once for each test pattern, and multiple paths can be tested using a single test pattern. The number of paths that can be associated with a single test pattern is defined as the path number limit. When the number of paths reaches the path number limit, the process completes. As long as the number of paths falls within the allowable range, the operation returns to S6 to select the next path. In generating test data, paths are associated with a single test pattern unless the required values are contradictory to each other.

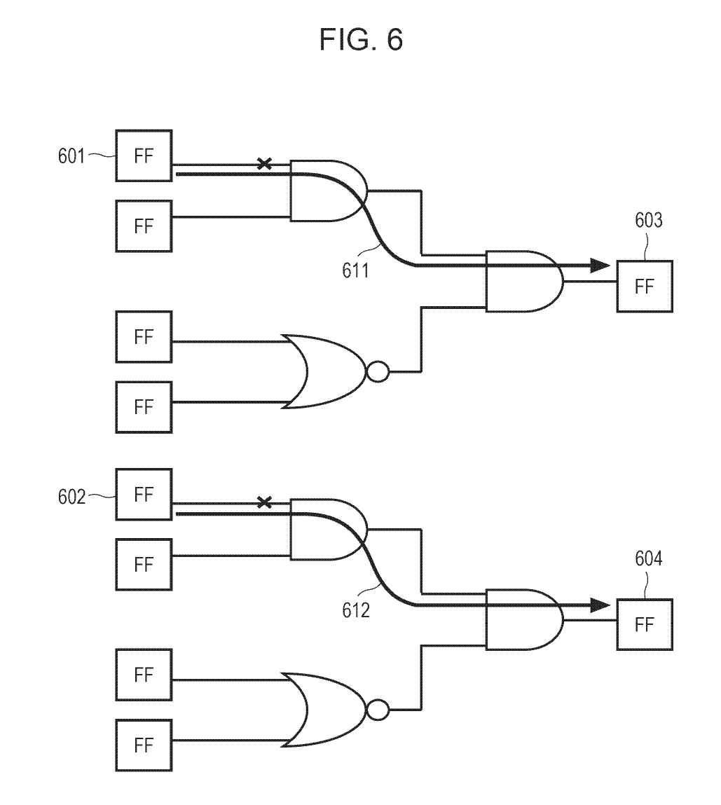

Referring now to FIG. 6, the relationship between paths that can be associated with the same test pattern according to this embodiment will be described. Two paths 611 and 612, one from a beginning latch 601 to an ending latch 603 and the other from a beginning latch 602 to an ending latch 604, can be associated with a single test pattern since the different paths have different ending latches.

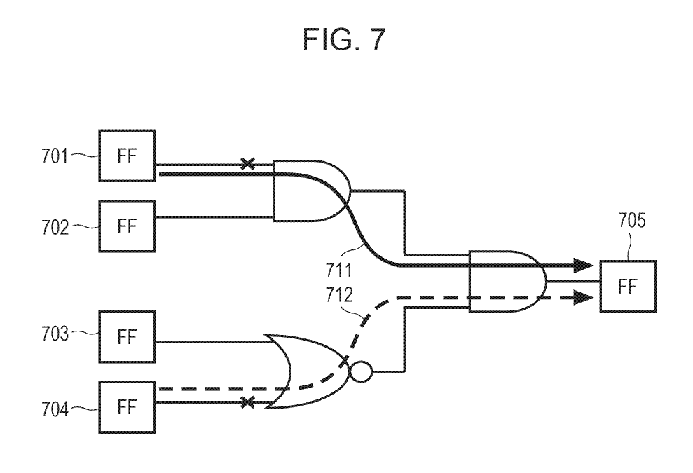

Conversely, in order to uniquely identify a false path by a test pattern that fails in a delay fault analysis, no paths having the same ending latch are associated with a single test pattern in this embodiment. FIG. 7 illustrates an example where paths are not associated with a single test pattern. In this case, a path 711 from a beginning latch 701 to an ending latch 705 indicated by a solid line and a path 712 from a beginning latch 704 to an ending latch 705 indicated by a broken line have the same ending latch 705. Accordingly, in this embodiment, the path 712 is not associated with the same test pattern.

Subsequently, the processor to be tested is tested by the testing unit 200 in accordance with the delay test data 56 generated as described above so as to determine whether the processor is non-faulty or faulty.

As described above, the pair of the beginning and ending latches is determined by SSTA. Thus, in SSTA, the path between the latches is ensured as a path making a large delay (a path making a large delay is selected) on the entire chip, whether the path is short or long, even when the delay made by the path can be reduced due to manufacturing variations. Accordingly, in generating a delay test, a test pattern can be generated using a method based on the conventional transition fault model. However, there remains a constraint that signal variations occur between the beginning and ending latches. According to this embodiment, in generating a delay test to screen a delay fault of a critical path, there is no need to see delay information. Thus, a test pattern can be generated using the conventional method based on the transition fault model.

As seen above, selection of a critical path based on only the result of STA does not necessarily result in accurate selection of paths that are critical on the actual chip. According to this embodiment, paths are narrowed down to some extent by STA, and the resultant paths are subjected to SSTA. This makes it possible to test paths having a high probability of being critical on the actual chip. Unlike the conventional method, this embodiment is a method of selecting only beginning latch-ending latch pairs to select paths. This realizes a mechanism where any path selected from the beginning latch-ending latch pairs has a high possibility of being a critical path. In the conventional method, a determination as to whether a selected path is a false path is made by trial and error; in the method according to this embodiment, such a determination can be reliably made according to whether the path is logically activated.

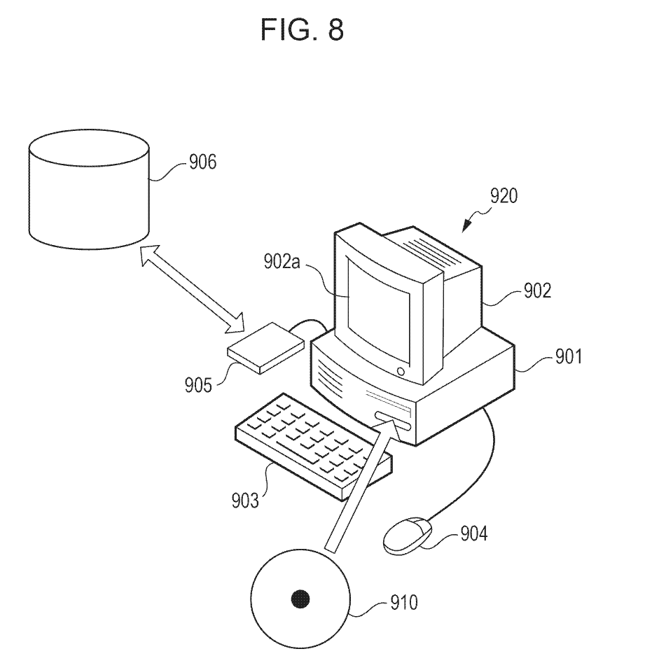

The present embodiment is applicable to computer systems as shown below. FIG. 8 is a drawing illustrating a computer system to which the present embodiment is applied. A computer system 920 illustrated in FIG. 8 includes a main body 901 that includes a central processing unit (CPU), a memory, and a disk drive, a display 902 that displays images in accordance with instructions from the main body 901, a keyboard 903 that is used to input various types of information into the computer system 920, a mouse 904 that is used to specify any position on a display screen 902a of the display 902, and a communication device 905 that is used to access external databases or the like to download programs or the like stored on other computer systems. Examples of the communication device 905 include network communication cards and modems.

A program for performing the above-mentioned steps can be provided to the above-mentioned computer system forming a delay test apparatus as a delay test program. By storing this program in a computer-readable storage medium, it can be executed by the computer system forming a delay test apparatus. The program for performing the above-mentioned steps is stored in a transportable storage medium such as a disk 910 or downloaded from a storage medium 906 of another computer system using the communication device 905. A delay test program (delay test software) for providing at least a delay test function to the computer system 920 is inputted into the computer system 920 and compiled. This program causes the computer system 920 to operate as a delay test apparatus having a delay test function. This program may be stored in a computer-readable storage medium such as the disk 910. Examples of a storage medium readable by the computer system 920 include internal storage devices incorporated into the computer such as a read only memory (ROM) or random access memory (RAM), transportable storage media such as the disk 910, flexible disks, digital versatile discs (DVDs), magneto-optical disks, and integrated circuit (IC) cards, databases storing computer programs, other computer systems and databases thereof, and various types of storage media accessible by a computer system connected via a communication means such as the communication device 905.

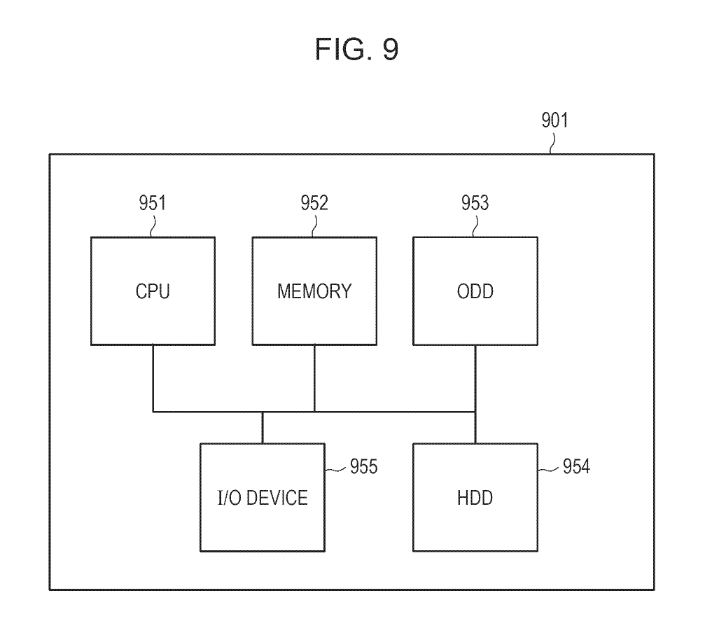

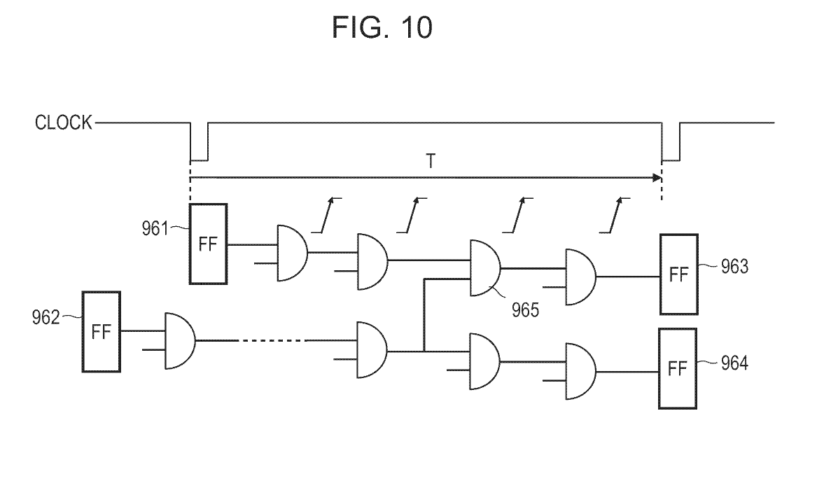

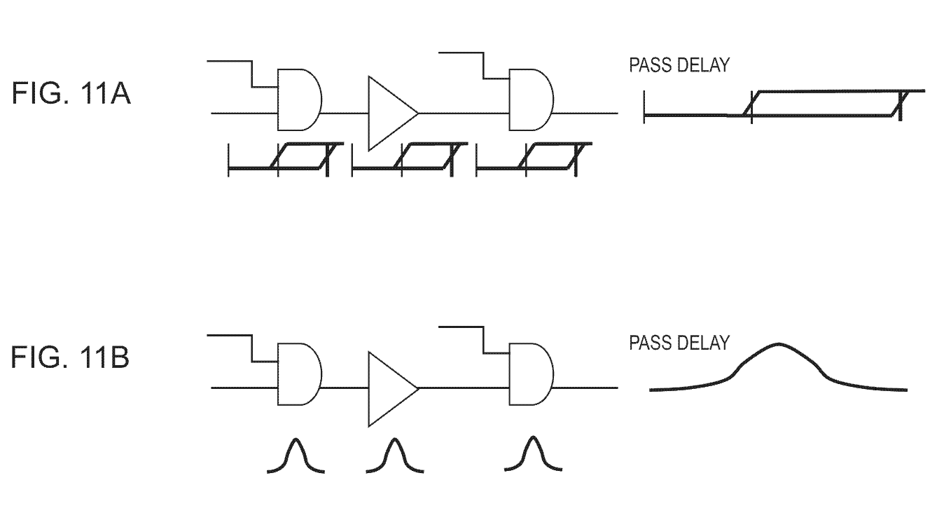

FIG. 9 is a diagram illustrating the hardware configuration of the main body 901 of the computer system 920. The main body 901 includes an optical disk drive (ODD) 953 that reads or writes data from or into a transportable storage medium such as a CPU 951, memory 952 (corresponding to the above-mentioned memory 61), and disk 910, and a hard disk drive (HDD) 954 that is a non-volatile storage means, as well as includes an I/O device 955 that controls communications with the outside. The above-mentioned function units are realized, for example, when the program previously stored in a non-volatile storage means such as the HDD 954 or disk 910 collaborates with the hardware resources such as the CPU 951 and memory 952. The above-mentioned pieces of data are stored in the HDD 954 or memory 952.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A delay test apparatus for a semiconductor integrated circuit, the delay test apparatus comprising:
a selecting unit that selects at least one pair of a beginning latch and an ending latch based on layout information of the semiconductor integrated circuit, the pair of the beginning latch and the ending latch possibly representing a critical path;
an analyzing unit that calculates a delay distribution for the selected critical path by executing statistical static timing analysis which accumulates a delay period, defined as a probability density function for each element, from the beginning latch to the ending latch selected by the selecting unit; and
a test generating unit that generates delay test data for the selected critical path by determining whether a signal inverted at the beginning latch is propagated to the ending latch based on the delay distribution calculated by the analyzing unit.

2. The delay test apparatus according to claim 1, wherein the selecting unit selects the at least one pair of the beginning latch and the ending latch as a result of static timing analysis which accumulates a delay period of each element from the beginning latch and the ending latch.

3. The delay test apparatus according to claim 1, wherein when the ending latches of at least two pairs selected by the selecting unit are the same and the delay test data has been generated for the path of one selected pair, the generating unit generates no delay test data for the path of the other pair.

4. The delay test apparatus according to claim 1, further comprising:
a test executing unit that executes a test of the manufactured semiconductor integrated circuit by using the delay test data generated by the generating unit.

5. The delay test apparatus according to claim 1, wherein the generating unit calculates a standard deviation of each the delay distribution calculated by the analyzing unit, calculates a value which is each the standard deviation multiplied by a predetermined constant, and sorts the calculated values in a descending order.

6. A delay test method for a semiconductor integrated circuit, the delay test method comprising:
selecting at least one pair of a beginning latch and an ending latch based on layout information of the semiconductor integrated circuit, the pair of the beginning latch and the ending latch possibly representing a critical path;
calculating a delay distribution for the selected critical path by executing statistical static timing analysis which accumulates a delay period, defined as a probability density function for each element, from the beginning latch to the ending latch selected by the selecting unit; and
generating delay test data for the selected critical path by determining in the sorted order whether a signal inverted at the beginning latch is propagated to the ending latch based on the calculated delay distribution.

7. The delay test method according to claim 6, wherein the at least one pair of the beginning latch and the ending latch is selected as a result of static timing analysis which accumulates a delay period of each element from the beginning latch and the ending latch.

8. The delay test method according to claim 6, wherein when the ending latches of at least two selected pairs are the same and the delay test data has been generated for the path of one selected pair, no delay test data for the path of the other pair is generated.

9. The delay test method according to claim 6, further comprising:
executing a test of the manufactured semiconductor integrated circuit by using the generated delay test data generated.

10. The delay test method according to claim 6, further comprising:
calculating a standard deviation of each the calculated delay distribution;
calculating a value which is each the calculated standard deviation multiplied by a predetermined constant; and
sorting the calculated values in a descending order.

11. A non-transient computer-readable recording medium storing a delay test program that causes a computer to execute a process for testing of a semiconductor integrated circuit, comprising:
selecting at least one pair of a beginning latch and an ending latch based on layout information of the semiconductor integrated circuit, the pair of the beginning latch and the ending latch possibly representing a critical path;
calculating a delay distribution for the selected critical path by executing statistical static timing analysis which accumulates a delay period, defined as a probability density function for each element, from the beginning latch to the ending latch selected by the selecting unit; and
generating delay test data for the selected critical path by determining in the sorted order whether a signal inverted at the beginning latch is propagated to the ending latch based on the calculated delay distribution.

12. The non-transient computer-readable recording medium according to claim 11, wherein the at least one pair of the beginning latch and the ending latch is selected as a result of static timing analysis which accumulates a delay period of each element from the beginning latch and the ending latch.

13. The non-transient computer-readable recording medium according to claim 11, wherein when the ending latches of at least two selected pairs are the same and the delay test data has been generated for the path of one selected pair, no delay test data for the path of the other pair is generated.

14. The non-transient computer-readable recording medium according to claim 11, further comprising:
executing a test of the manufactured semiconductor integrated circuit by using the generated delay test data generated.

15. The non-transient computer-readable recording medium according to claim 11, further comprising:
calculating a standard deviation of each the calculated delay distribution;
calculating a value which is each the calculated standard deviation multiplied by a predetermined constant; and
sorting the calculated values in a descending order.
